(19) United States
(12) Patent Application Publication
(10) Pub. No.: US 2015/0075570 A1
(43) Pub. Date: Mar. 19, 2015

(54) METHODS FOR THE SELECTIVE REMOVAL OF ASHED SPIN-ON GLASS

(71) Applicant: ADVANCED TECHNOLOGY MATERIALS, INC., Danbury, CT (US)

(72) Inventors: Hsing-chen Wu, Yonghe City (TW); Sheng-hung Tu, Yonghe City (TW)

(73) Assignee: ENTEGRIS, INC., Danbury, CT (US)

(21) Appl. No.: 14/384,303

(22) PCT Filed: Mar. 12, 2013
(86) PCT No.: PCT/US2013/030370

§ 371 Date: Sep. 10, 2014

Related U.S. Application Data
(60) Provisional application No. 61/609,658, filed on Mar. 12, 2012.

(51) Int. Cl. C11D 11/00; H01L 21/311; C11D 3/04; H01L 21/02; C11D 3/00; C11D 3/43

(52) U.S. Cl. CPC C11D 11/0047; C11D 3/0073; C11D 3/43; C11D 3/046; H01L 21/02071; H01L 21/31111
USPC 134/41; 134/42

(57) ABSTRACT

A semi-aqueous removal composition and process for selectively removing spin-on glass relative to a metal gate and/or ILD material from a microelectronic device having said material thereon. The semi-aqueous removal composition can be a fluoride-containing composition or an alkaline composition.

### FIELD

The present invention relates to compositions and methods for selectively removing one metal gate material relative to a second metal gate material from a substrate comprising same. The substrate preferably comprises a high-k/metal gate integration scheme.

### DESCRIPTION OF THE RELATED ART

Spin-on glass (SOG) films have been used for various purposes in semiconductor devices including, but not limited to, insulation between multilayer metallizations; contouring steps in oxides or metals for improved step coverage; preventatives for auto-doping; back-filling packages; diffusion masks; and planarizing.

A spin-on glass composition is a liquid, silica-based composition that can be applied to the surface of a semiconductor wafer and spun with the wafer to provide a coating with a level top surface. With this technique, the spin-on glass composition will fill in any valleys or recessed areas in the surface of the semiconductor wafer that result from the various insulating and conductive regions. The spin-on glass coating is then dried to form a solid layer and is subsequently cured at high temperatures to form a hard silica-based (glassy) layer. This hard layer may be etched in preparation for further processing.

Disadvantageously, to date, the selectivity of removal of spin-on glasses relative to other layers that may be exposed, such as interlevel dielectrics (ILD) and metal gate material, has been quite low. More specifically, the selective etching of spin-on glasses relative to the ILD's and gate metals has been challenging because the etchants are known to readily attack the SOG, the ILD and the gate metals.

It would therefore be a significant advance in the art to provide a composition that can selectively remove spin-on glass and related materials relative to other materials present on the surface of the microelectronic device such as ILD and gate metals.

### SUMMARY OF THE INVENTION

The present invention generally relates to compositions and methods for selectively removing spin-on glass relative to other material layers present on a substrate. More preferably, the present invention relates to compositions and methods for selectively removing treated spin-on glass relative to other material layers present on a substrate. The other material layers include interlevel dielectric layers and metal gate materials such as TiNₓ and TaNₓ.

In one aspect, a method of selectively removing spin-on glass relative to a material selected from the group consisting of metal gate material, ILD material, and combinations thereof is described, said method comprising contacting a substrate comprising the spin-on glass and the material with a removal composition, wherein the removal composition selectively removes the spin-on glass relative to the material.

Other aspects, features and advantages of the invention will be more fully apparent from the ensuing disclosure and appended claims.

### DETAILED DESCRIPTION, AND PREFERRED EMBODIMENTS THEREOF

The present invention generally relates to compositions and methods for selectively removing spin-on glass relative to other material layers present on a substrate. More preferably, the present invention relates to compositions and methods for selectively removing treated spin-on glass relative to other material layers present on a substrate. The other material layers include interlevel dielectric layers and metal gate materials such as TiNₓ and TaNₓ.

For ease of reference, “microelectronic device” corresponds to semiconductor substrates, flat panel displays, phase change memory devices, solar panels and other products including solar cell devices, photovoltaics, and microelectromechanical systems (MEMS), manufactured for use in microelectronic, integrated circuit, energy collection, or computer chip applications. It is to be understood that the terms “microelectronic device,” “microelectronic substrate” and “microelectronic device structure” are not meant to be limiting in any way and include any substrate or structure that will eventually become a microelectronic device or microelectronic assembly. The microelectronic device can be patterned, blanketed, a control and/or a test device.

As defined herein, “spin-on glass” (SOG) corresponds to silicates, polysiloxanes or other organosilicon glass resins which are deposited using inexpensive, conventional spin-on deposition techniques. Spin-on glasses (SOGs) are proprietary liquid solutions containing siloxane, silicate or organosilicon-based monomers dissolved in various kinds of solvents or alcohols. During coating and curing, monomers are polymerized by condensation and release water, alcohol and other solvents. The cured material is a thin solid film having mechanical, chemical and electrical properties that depend on the starting solution, and the coating and curing process. An organosilicon glass resin, for present purposes, is a polymer, having a noncrystalline structure, which includes silicon, oxygen, carbon and hydrogen. Polysiloxanes can contain varying concentrations of methyl and phenyl groups. After baking, these spin-on glass resins have etch characteristics essentially equivalent to those of silicon dioxide, e.g., they are readily plasma or reactive ion etched in, for example, CHF₃ and O₂ (or air) plasmas.

As defined herein, “treated spin-on glass” corresponds to spin-on glass that has been processed such that the glass layer is more porous post-processing than it was pre-processing. For example, during a plasma etching process, the spin-on glass layer loses much of its remaining carbon and the remaining layer is porous. Preferably, the spin-on glass is plasma etched.

As defined herein, “metal gate material” corresponds to materials having a Fermi level corresponding to the mid-gap of the semiconductor substrate such as Ti, Ta, W, Mo, Ru, Al, La, titanium nitride, tantalum nitride, tantalum carbide, titanium carbide, molybdenum nitride, tungsten nitride, ruthenium (IV) oxide, tantalum silicon nitride, titanium silicon nitride, tantalum carbon nitride, titanium carbon nitride, titanium aluminide, tantalum aluminide, titanium aluminum nitride, tantalum aluminum nitride, lanthanum oxide, or combinations thereof. It should be appreciated that the compounds disclosed as metal gate materials may have varying stoichiometries. Accordingly, titanium nitride will be represented as TiNₓ herein, tantalum nitride will be represented as TaNₓ herein, and so on.

Metal lines within patterned metal layers are insulated by layers known as “interlevel dielectrics” or “interlayer dielectrics” (both use the ILD acronym). The interlevel dielectrics insulate the metal lines from any undesired electrical contact both with other metal lines, whether in the same or another metal layer, and with other circuit elements. Preferably, the ILD comprises a low-k dielectric material. As defined herein, “low-k dielectric material” corresponds to any material used as a dielectric material in a layered microelectronic device, wherein the material has a dielectric constant less than about 3.5. Preferably, the low-k dielectric materials include low-polarity materials such as silicon-containing organic polymers, silicon-containing hybrid organic/inorganic materials, organosilicate glass (OSG), TEOS, fluorinated silicate glass (FSG), silicon dioxide, and carbon-doped oxide (CDO) glass. It is to be appreciated that the low-k dielectric materials may have varying densities and varying porosities.

“Post-etch residue” and “post-plasma etch residue,” as used herein, corresponds to material remaining following gas-phase plasma etching processes, e.g., BEOL dual-damascene processing. The post-etch residue may be organic, organometallic, organosilicic, or inorganic in nature, for example, silicon-containing material, titanium-containing material, nitrogen-containing material, oxygen-containing material, polymeric residue material, copper-containing residue material (including copper oxide residue), tungsten-containing residue material, cobalt-containing residue material, etch gas residue such as chlorine and fluorine, and combinations thereof.

As used herein, “about” is intended to correspond to ±5% of the stated value.

“Substantially devoid” is defined herein as less than 2 wt. %, preferably less than 1 wt. %, more preferably less than 0.5 wt. %, even more preferably less than 0.1 wt. %, and most preferably 0 wt. %.

As used herein, the “removal composition selectively removes the spin-on glass relative to the metal gate material” corresponds to etch rate selectivity of about 2:1 to about 1000:1, preferably about 2:1 to about 100:1, and most preferably about 3:1 to about 50:1. In other words, when the etch rate of the spin-on glass is 2 Å min⁻¹ (or up to 1000 Å min⁻¹), the etch rate of the metal gate material is 1 Å min⁻¹.

As used herein, the “removal composition selectively removes the spin-on glass relative to the ILD material” corresponds to etch rate selectivity of about 2:1 to about 1000:1, preferably about 2:1 to about 100:1, and most preferably about 3:1 to about 50:1. In other words, when the etch rate of the spin-on glass is 2 Å min⁻¹ (or up to 1000 Å min⁻¹), the etch rate of the ILD material is 1 Å min⁻¹.

Compositions of the invention may be embodied in a wide variety of specific formulations, as hereinafter more fully described.

In all such compositions, wherein specific components of the composition are discussed in reference to weight percentage ranges including a zero lower limit, it will be understood that such components may be present or absent in various specific embodiments of the composition, and that in instances where such components are present, they may be present at concentrations as low as 0.001 weight percent, based on the total weight of the composition in which such components are employed.

In a first aspect, a method of selectively removing spin-on glass relative to metal gate material is described, said method comprising contacting a substrate comprising the spin-on glass and the metal gate material with a removal composition, wherein the removal composition selectively removes the spin-on glass relative to the metal gate material. In one embodiment, the spin-on glass has been treated. In another embodiment, the metal gate material comprises titanium. In still another embodiment, the spin-on glass has been treated and the metal gate material comprises titanium. In yet another embodiment, the spin-on glass has been plasma etched and the metal gate material comprises titanium. In another embodiment, the spin-on glass has been plasma etched and the metal gate material comprises titanium nitride.

In a second aspect, a method of selectively removing spin-on glass relative to ILD material is described, said method comprising contacting a substrate comprising the spin-on glass and the ILD material with a removal composition, wherein the removal composition selectively removes the spin-on glass relative to the ILD material. In one embodiment, the spin-on glass has been treated. In another embodiment, the ILD material comprises a low-k dielectric. In still another embodiment, the spin-on glass has been treated and the ILD material comprises a low-k dielectric. In still another embodiment, the spin-on glass has been plasma etched and the ILD material comprises a low-k dielectric.

In a third aspect, a method of selectively removing spin-on glass relative to metal gate material and ILD material is described, said method comprising contacting a substrate comprising the spin-on glass, the metal gate material and the ILD material with a removal composition, wherein the removal composition selectively removes the spin-on glass relative to the metal gate material and the ILD material. In one embodiment, the spin-on glass has been treated. In another embodiment, the metal gate material comprises titanium, more preferably titanium nitride. In still another embodiment, the ILD comprises a low-k dielectric. In yet another embodiment, the spin-on glass has been plasma etched and the metal gate material comprises titanium. In yet another embodiment, the spin-on glass has been plasma etched and the metal gate material comprises titanium nitride. Preferably, the ILD comprises a low-k dielectric.

The method of the first through third aspect selectively removes the spin-on glass relative to the metal gate and/or ILD material at temperatures in a range from about room temperature to about 100° C., preferably about 20° C. to about 60° C. It should be appreciated by the skilled artisan that the time of removal varies depending on whether the removal is performed in a single wafer tool or a multiple wafer tool, wherein time preferentially is in a range from about 10 sec to about 30 minutes. Such contacting times and temperatures are illustrative, and any other suitable time and temperature conditions may be employed that are efficacious to selectively remove the spin-on glass relative to the metal gate and/or ILD material from the substrate.

Preferably the removal rate of the metal gate material is less than about 2 Å min⁻¹, more preferably less than about 1 Å min⁻¹. Preferably, the removal rate of the ILD is less than about 50 Å min⁻¹, more preferably less than about 20 Å min⁻¹, even more preferably less than about 10 Å min⁻¹ These preferred rates combined with treated SOG etch rates of about 500-2000 Å min⁻¹ give selectivities in the range of about 10:1 to more than about 100:1.

In a fourth aspect, a removal composition comprising an etchant is described. Preferably, the removal composition comprising the etchant is used in the methods of the first through third aspects. In broad terms, the etchant comprises a fluoride source. Accordingly, in one embodiment, the removal composition is a fluoride-containing removal composition, said fluoride-containing removal composition including at least one fluoride, at least one metal corrosion inhibitor, water, and optionally at least one organic solvent, for selectively removing a spin-on glass relative to a metal gate and/or ILD material. In a preferred embodiment, the fluoride-containing removal composition is buffered. In one embodiment, the fluoride-containing removal composition comprises, consists of, or consists essentially of at least one fluoride, at least one metal corrosion inhibitor, and water. In yet another embodiment, the fluoride-containing removal composition comprises, consists of, or consists essentially of at least one fluoride, at least one metal corrosion inhibitor, at least one organic solvent, and water. In still another embodiment, fluoride-containing removal composition comprises, consists of, or consists essentially of buffered fluoride, at least one metal corrosion inhibitor, at least one organic solvent, and water. In yet another embodiment, the fluoride-containing removal composition comprises, consists of, or consists essentially of buffered fluoride, at least one metal corrosion inhibitor, and water. The pH of the fluoride-containing removal composition is preferably less than 7.

The water is preferably deionized. In a preferred embodiment of the invention, the fluoride-containing removal composition, prior to contact of the removal composition with the substrate, is substantially devoid of chemical mechanical polishing abrasive or other inorganic particulate material, silicic acid, surfactant(s), oxidizing agent(s), polymeric species selected from the group consisting of a polypropylenimine dendrimer, a poly(vinyl amine), a polyamine, a polyimidamine, a polyethylimine, a polyamidamine, a poly quaternary amine, a polyvinyl amide, a polyacrylamide, a linear or branched polyethylenimine, and copolymers that may comprise or consist of the aforementioned homopolymers, or any combination thereof.

The at least one fluoride source includes, but is not limited to, hydrofluoric acid, ammonium fluoride, ammonium bifluoride, hexafluorosilicic acid (HFSA), ammonium hexafluorosilicate, tetrafluoroboric acid, ammonium tetrafluoroborate, tetrabutylammonium tetrafluoroborate (TBA-BF₄), hexafluorotantalic acid, ammonium hexafluorotantalate, hexafluorotitanic acid, ammonium hexafluorotitanate, and combinations thereof. Preferably, the fluoride source comprises ammonium fluoride or HFSA. It is noted that HFSA can be generated in situ from HF and fine SiO₂ or a tetraalkoxysilane such as tetraethoxysilane (TEOS).

Metal corrosion inhibitors preferably inhibit the removal of the metal gate material relative to the spin-on glass and include, but are not limited to, boric acid, ammonium borates, ascorbic acid, L(+)-ascorbic acid, isoascorbic acid, ascorbic acid derivatives, gallic acid, glycine, serine, proline, leucine, alanine, asparagine, aspartic acid, glutamine, valine, lysine, iminodiacetic acid (IDA), boric acid, nitrilotriacetic acid, malic acid, acetic acid, maleic acid, 2,4-pentanedione, phosphonic acids such as 1-hydroxyethylidene-1,1-diphosphonic acid (HEDP), 1-hydroxyethane-1,1-diphosphonic acid, nitrilotris(methylenephosphonic acid) (NTMP), N,N,N′,N′-ethylenediaminetetra(methylenephosphonic)acid (EDTMP), 1,5,9-triazacyclododecane-N,N′,N″-tris(methylenephosphonic acid) (DOTRP), 1,4,7,10-tetraazacyclododecane-N,N′,N″,N′″-tetrakis(methylenephosphonic acid) (DOTP), diethylenetriaminepenta(methylenephosphonic acid) (DETAP), aminotri(methylenephosphonic acid), bis(hexamethylene)triamine phosphonic acid, 1,4,7-triazacyclononane-N,N′,N″-tris(methylenephosphonic acid (NOTP), esters of phosphoric acids; 5-amino-1,3,4-thiadiazole-2-thiol (ATDT), benzotriazole (BTA), citric acid, ethylenediamine, oxalic acid, tannic acid, ethylenediaminetetraacetic acid (EDTA), uric acid, 1,2,4-triazole (TAZ), tolyltriazole, 5-phenyl-benzotriazole, 5-nitro-benzotriazole, 3-amino-5-mercapto-1,2,4-triazole, 1-amino-1,2,4-triazole, hydroxybenzotriazole, 2-(5-amino-pentyl)-benzotriazole, 1-amino-1,2,3-triazole, 1-amino-5-methyl-1,2,3-triazole, 3-amino-1,2,4-triazole, 3-mercapto-1,2,4-triazole, 3-isopropyl-1,2,4-triazole, 5-phenylthiol-benzotriazole, halo-benzotriazoles (halo=F, Cl, Br or I), naphthotriazole, 2-mercaptobenzimidazole (MBI), 2-mercaptobenzothiazole, 4-methyl-2-phenylimidazole, 2-mercaptothiazoline, 5-aminotetrazole, 2,4-diamino-6-methyl-1,3,5-triazine, thiazole, triazine, methyltetrazole, 1,3-dimethyl-2-imidazolidinone, 1,5-pentamethylenetetrazole, 1-phenyl-5-mercaptotetrazole, diaminomethyltriazine, imidazoline thione, mercaptobenzimidazole, 4-methyl-4H-1,2,4-triazole-3-thiol, benzothiazole, tritolyl phosphate, imidazole, indiazole, benzoic acid, malonic acid, ammonium benzoate, catechol, 4-tert-butyl catechol, pyrogallol, resorcinol, hydroquinone, cyanuric acid, barbituric acid and derivatives such as 1,2-dimethylbarbituric acid, alpha-keto acids such as pyruvic acid, adenine, purine, glycine/ascorbic acid, Dequest 2000, Dequest 7000, p-tolylthiourea, succinic acid, phosphonobutane tricarboxylic acid (PBTCA), and combinations thereof. If the surface of the microelectronic device comprises aluminum (e.g., an Al—Cu alloy), phosphate compounds may be added to inhibit the corrosion of same. Aluminum metal corrosion inhibitors contemplated include, but are not limited to, alkyl phosphates (e.g., triisobutyl phosphate, mono(2-ethylhexyl)phosphate, tris(2-ethylhexyl)phosphate, bis(2-ethylhexyl)phosphate, tributyl phosphate, 2-ethylhexyl phosphate, dibutyl hydrogen phosphate) and phosphoric acid, and derivatives thereof. It should be appreciated that the aluminum metal corrosion inhibitors can be combined with at least one of the other enumerated metal corrosion inhibitors. Preferably, the metal corrosion inhibitor comprises HEDP, NTMP, IDA, or any combination thereof.

The at least one organic solvent for the composition of the fourth aspect may comprise a glycol solvent selected from the group consisting of ethylene glycol, propylene glycol, diethylene glycol, dipropylene glycol, glycerol, a monoglyceride, a diglyceride, a glycol ether, and combinations thereof, wherein the glycol ether comprises a species selected from the group consisting of diethylene glycol monomethyl ether, triethylene glycol monomethyl ether, diethylene glycol monoethyl ether, triethylene glycol monoethyl ether, ethylene glycol monopropyl ether, ethylene glycol monobutyl ether, diethylene glycol monobutyl ether (i.e., butyl carbitol), triethylene glycol monobutyl ether, ethylene glycol monohexyl ether, diethylene glycol monohexyl ether, ethylene glycol phenyl ether, propylene glycol methyl ether, dipropylene glycol methyl ether, tripropylene glycol methyl ether, dipropylene glycol dimethyl ether, dipropylene glycol ethyl ether, propylene glycol n-propyl ether, dipropylene glycol n-propyl ether (DPGPE), tripropylene glycol n-propyl ether, propylene glycol n-butyl ether, dipropylene glycol n-butyl ether, tripropylene glycol n-butyl ether, propylene glycol phenyl ether, and combinations thereof. Preferably, the at least one organic solvent of the fourth aspect comprises ethylene glycol.

When the fluoride-containing removal compositions are buffered, a buffering agent such as a salt of the conjugate base of the fluoride source or ammonia is preferably added to the composition. For example, when the fluoride source is HFSA, a salt of hexafluorosilicate may be added, such as ammonium hexafluorosilicate, sodium hexafluorosilicate, or potassium hexafluorosilicate. When the fluoride source is HF, a salt of fluoride can be added, such as ammonium fluoride or ammonium bifluoride. Ammonia or quaternary ammonium hydroxides (e.g., TMAH, TEAH, etc.) may be added to buffer the composition. It should be appreciated that the buffering agents are not limited to those enumerated here and are readily determined by the skilled artisan based on the fluoride source of choice.

In a first embodiment of the composition of the fourth aspect, the fluoride-containing removal composition comprises, consists of, or consists essentially of a buffered fluoride, a glycol solvent, at least one metal corrosion inhibitor and water. The fluoride-containing removal composition can comprise, consist of, or consist essentially of a buffered fluoride, a glycol solvent, a phosphonic acid, and water. Alternatively, the fluoride-containing removal composition can comprise, consist of, or consist essentially of a buffered ammonium fluoride, a glycol solvent, a phosphonic acid, and water. In yet another alternative, the fluoride-containing removal composition can comprise, consist of, or consist essentially of a buffered ammonium fluoride, a glycol solvent, a phosphonic acid, at least one additional corrosion inhibitor, and water. Preferably, the buffered ammonium fluoride includes the combination of ammonium fluoride and ammonia. Accordingly, in still another alternative, the fluoride-containing removal composition can comprise, consist of, or consist essentially of NH₄F, NH₃ or TMAH, HEDP, IDA, a glycol and/or glycol ether solvent, and water. In yet another alternative, the fluoride-containing removal composition can comprise, consist of, or consist essentially of NH₄F, NH₃ or TMAH, HEDP, IDA, ethylene glycol, and water. In still another alternative, the fluoride-containing removal composition can comprise, consist of, or consist essentially of NH₄F, NH₃ or TMAH, HEDP, IDA, propylene glycol, and water. The fluoride-containing removal composition of each of these embodiments is preferably substantially devoid of abrasive or other inorganic particulate material, silicic acid, surfactant(s), oxidizing agent(s), and polymeric species as described above. The pH of the fluoride-containing removal composition of each of these embodiments is preferably in a range from about 3 to about 7. Preferably, the removal compositions of this first embodiment have about 0.01 wt % to about 10 wt % of the at least one fluoride, about 0.01 wt % to about 2 wt % buffering agent, about 0.01 wt % to about 10 wt % of the at least one metal corrosion inhibitor, about 10 wt % to about 90 wt % of the at least one organic solvent, and about 10 wt % to about 95 wt % water. More preferably, the removal compositions of this embodiment have about 0.5 wt % to about 8 wt % of the at least one fluoride, about 0.01 wt % to about 1.5 wt % buffering agent, about 0.5 wt % to about 5 wt % of the at least one metal corrosion inhibitor, about 45 wt % to about 75 wt % of the at least one organic solvent, and about 10 wt % to about 50 wt % water.

In second embodiment of the composition of the fourth aspect, the fluoride-containing removal composition comprises, consists of, or consists essentially of a buffered fluoride, at least one metal corrosion inhibitor and water. The fluoride-containing removal composition can comprise, consist of, or consist essentially of a buffered fluoride, a phosphonic acid, and water. Alternatively, the fluoride-containing removal composition can comprise, consist of, or consist essentially of a buffered hexafluorosilicic acid, a phosphonic acid, and water. In yet another alternative, the fluoride-containing removal composition can comprise, consist of, or consist essentially of HFSA, AHFS, HEDP, and water. In still another alternative, the fluoride-containing removal composition can comprise, consist of, or consist essentially of HFSA, AHFS, NTMP, and water. The fluoride-containing removal composition of each of these embodiments is preferably substantially devoid of abrasive or other inorganic particulate material, silicic acid, surfactant(s), oxidizing agent(s), quaternary ammonium hydroxide(s), and polymeric species as described above. The pH of the fluoride-containing removal composition of each of these embodiments is preferably less than about 2, more preferably less than about 1. Preferably, the removal compositions of this second embodiment have about 0.01 wt % to about 10 wt % of the at least one fluoride, about 0.01 wt % to about 10 wt % buffering agent, about 0.01 wt % to about 10 wt % of the at least one metal corrosion inhibitor, and about 50 wt % to about 99 wt % water. More preferably, the removal compositions of this embodiment have about 1 wt % to about 8 wt % of the at least one fluoride, about 1 wt % to about 5 wt % buffering agent, about 1 wt % to about 5 wt % of the at least one metal corrosion inhibitor, and about 75 wt % to about 90 wt % water.

In a preferred embodiment, the removal composition of the fourth aspect comprises, consists of, or consists essentially of about 0.01 wt % to about 10 wt % of at least one fluoride, about 0.01 wt % to about 20 wt % at least one metal nitride corrosion inhibitor, optionally at least one oxidizing agent, optionally at least one surfactant, and about 55 wt % to about 99 wt % water. More preferred, the removal composition of the fourth aspect comprises, consists of, or consists essentially of about 0.01 wt % to about 2 wt % of at least one fluoride, about 0.01 wt % to about 10 wt % at least one metal nitride corrosion inhibitor, optionally at least one oxidizing agent, optionally at least one surfactant, and about 84 wt % to about 99.5 wt % water water. When present the amount of at least one oxidizing agent is about 0.01 wt % to about 10 wt %, preferably about 0.5 wt % to about 3 wt %. When present the amount of at least one surfactant is about 0.01 wt % to about 5 wt %, preferably about 0.01 wt % to about 1 wt %.

In a fifth aspect, a removal composition comprising an etchant is described. Preferably, the removal composition comprising the etchant is used in the methods of the first through third aspects. In broad terms, the etchant comprises a hydroxide source or amine Accordingly, in one embodiment, the alkaline removal composition includes at least one quaternary ammonium hydroxide or amine, at least one organic solvent, at least one alkali or alkaline earth metal salt (including hydroxides), water, and optionally at least one metal corrosion inhibitor, for selectively removing a spin-on glass relative to a metal gate and/or ILD material. In one embodiment, the alkaline removal composition comprises, consists of, or consists essentially of at least one quaternary ammonium hydroxide or amine, at least one organic solvent, at least one alkali or alkaline earth metal salt, and water. In yet another embodiment, the alkaline removal composition comprises, consists of, or consists essentially of at least one quaternary ammonium hydroxide or amine, at least one organic solvent, at least one alkali or alkaline earth metal salt, at least one metal corrosion inhibitor, and water. The pH of the alkaline removal composition is preferably greater than 10, more preferably greater than 12, and most preferably greater than 13.

The water is preferably deionized. In a preferred embodiment of the invention, the alkaline removal composition is substantially devoid of abrasive or other inorganic particulate material, surfactant(s), oxidizing agent(s), fluoride source(s), or any combination thereof. The metal corrosion inhibitors were described hereinabove.

The at least one quaternary ammonium hydroxide comprises a compound of the formula [NR¹R²R³R⁴]OH, wherein R¹, R², R³ and R⁴ may be the same as or different from one another and are selected from the group consisting of hydrogen, straight-chained or branched C₁-C₆ alkyl (e.g., methyl, ethyl, propyl, butyl, pentyl, and hexyl), and substituted or unsubstituted C₆-C₁₀ aryl, e.g., benzyl, including tetramethylammonium hydroxide (TMAH), tetrapropylammonium hydroxide (TPAH), tetrabutylammonium hydroxide, tetraethylammonium hydroxide, benzyltriethylammonium hydroxide, benzyltrimethylammonium hydroxide, tributylmethylammonium hydroxide, ammonium hydroxide, tetrabutylphosphonium hydroxide (TBPH), (2-hydroxyethyl)trimethylammonium hydroxide, (2-hydroxyethyl)triethylammonium hydroxide, (2-hydroxyethyl)tripropylammonium hydroxide, (1-hydroxypropyl)trimethylammonium hydroxide, ethyltrimethylammonium hydroxide, diethyldimethylammonium hydroxide (DEDMAH), and combinations thereof. The at least one amine comprises a compound selected from the group consisting of 1,1,3,3-tetramethylguanidine (TMG), guanidine carbonate, arginine, monoethanolamine (MEA), diethanolamine (DEA), triethanolamine (TEA), ethylenediamine, cysteine, and combinations thereof.

The at least one organic solvent for the composition of the fifth aspect may comprise methanol, ethanol, isopropanol, and higher alcohols (including diols, triols, etc.), tetrahydrofuran (THF), N-methylpyrrolidinone (NMP), cyclohexylpyrrolidinone, N-octylpyrrolidinone, N-phenylpyrrolidinone, methyl formate, dimethyl formamide (DMF), dimethylsulfoxide (DMSO), tetramethylene sulfoxide, dimethyl sulfite, 3-chloro-1,2-propanediol, tetramethylene sulfone (sulfolane), diethyl ether, phenoxy-2-propanol (PPh), propriophenone, ethyl lactate, ethyl acetate, ethyl benzoate, acetonitrile, acetone, ethylene glycol, propylene glycol, dioxane, butyryl lactone, butylene carbonate, ethylene carbonate, propylene carbonate, or a glycol solvent as described hereinabove. It will be obvious to those skilled in the art that when an ester or an amide is chosen to serve as the organic solvent in the composition, it is preferably mixed with the bases shortly before processing in order to minimize the reaction between the two. Preferably, the at least one organic solvent of the fifth aspect comprises DMSO.

The at least one alkali or alkaline earth metal salt can include any salt of sodium, potassium rubidium, cesium, magnesium, calcium, strontium or barium. Contemplated salts include chlorides, bromides, iodides, carbonates, hydroxides, sulfates, phosphates, acetates, nitrates, nitrites, and sulfites. Preferably, the at least one alkali or alkaline earth metal salt comprises cesium chloride or cesium hydroxide.

The composition of the fifth aspect preferably comprises, consists of, or consists essentially of a quaternary ammonium hydroxide or amine, at least one organic solvent, an alkali or alkaline earth metal salt, and water. The alkaline removal composition can comprise, consist of, or consist essentially of a quaternary ammonium hydroxide or amine, at least one organic solvent, CsCl or CsOH, and water. Alternatively, the alkaline removal composition can comprise, consist of, or consist essentially of a quaternary ammonium hydroxide or amine, DMSO, CsCl or CsOH, and water. In yet another alternative, the alkaline removal composition can comprise, consist of, or consist essentially of BTMAH, DMSO, CsCl or CsOH, and water. The alkaline removal composition of each of these embodiments is preferably substantially devoid of abrasive or other inorganic particulate material, surfactant(s), oxidizing agent(s), fluoride source(s), or any combination thereof as described above. Preferably, the removal compositions of this aspect have about 0.01 wt % to about 40 wt % of the at least one quaternary ammonium hydroxide or amine, about 1 wt % to about 30 wt % of the at least one organic solvent, about 0.01 wt % to about 5 wt % of the at least one alkali or alkaline earth metal salt, and about 10 wt % to about 95 wt % water. More preferably, the removal compositions of this aspect have about 0.1 wt % to about 20 wt % of the at least one quaternary ammonium hydroxide or amine, about 5 wt % to about 20 wt % of the at least one organic solvent, about 0.1 wt % to about 3 wt % of the at least one alkali or alkaline earth metal salt, and about 50 wt % to about 90 wt % water.

In another aspect of the present invention, any of the removal compositions described herein may further include dissolved spin-on glass. For example, the fluoride-containing removal compositions may comprise, consist essentially of, or consist of at least one fluoride, at least one metal corrosion inhibitor, water, dissolved spin-on glass, and optionally at least one organic solvent. In another embodiment, the fluoride-containing removal compositions may comprise, consist essentially of, or consist of buffered fluoride, at least one metal corrosion inhibitor, water, dissolved spin-on glass, and optionally at least one organic solvent. In another embodiment, the alkaline removal compositions may comprise, consist of, or consist essentially of at least one quaternary ammonium hydroxide or amine, at least one organic solvent, at least one alkali or alkaline earth metal salt, water, dissolved spin-on glass, and optionally at least one metal corrosion inhibitor.

It will be appreciated that it is common practice to make concentrated forms of the removal compositions of the fourth or fifth aspects to be diluted prior to use. For example, the removal composition may be manufactured in a more concentrated form, and thereafter diluted with water and/or the organic solvent at the manufacturer, before use, and/or during use at the fab. Dilution ratios may be in a range from about 0.1 part diluent:1 part removal composition concentrate to about 100 parts diluent:1 part removal composition concentrate.

The removal compositions of the fourth or fifth aspects are easily formulated by simple addition of the respective ingredients and mixing to homogeneous condition. Furthermore, the removal compositions may be readily formulated as single-package formulations or multi-part formulations that are mixed at or before the point of use, preferably multi-part formulations. The individual parts of the multi-part formulation may be mixed at the tool or in a mixing region/area such as an inline mixer or in a storage tank upstream of the tool. It is contemplated that the various parts of the multi-part formulation may contain any combination of ingredients/constituents that when mixed together form the desired removal composition. The concentrations of the respective ingredients may be widely varied in specific multiples of the removal composition, i.e., more dilute or more concentrated, in the broad practice of the invention, and it will be appreciated that the removal compositions of the invention can variously and alternatively comprise, consist or consist essentially of any combination of ingredients consistent with the disclosure herein.

Accordingly, a sixth aspect relates to a kit including, in one or more containers, one or more components adapted to form the compositions of the fourth or fifth aspects. The containers of the kit must be suitable for storing and shipping said removal compositions, for example, NOWPak® containers (Advanced Technology Materials, Inc., Danbury, Conn., USA). The one or more containers which contain the components of the respective removal composition preferably include means for bringing the components in said one or more containers in fluid communication for blending and dispense. For example, referring to the NOWPak® containers, gas pressure may be applied to the outside of a liner in said one or more containers to cause at least a portion of the contents of the liner to be discharged and hence enable fluid communication for blending and dispense. Alternatively, gas pressure may be applied to the head space of a conventional pressurizable container or a pump may be used to enable fluid communication. In addition, the system preferably includes a dispensing port for dispensing the blended removal composition to a process tool.

Substantially chemically inert, impurity-free, flexible and resilient polymeric film materials, such as high density polyethylene, are preferably used to fabricate the liners for said one or more containers. Desirable liner materials are processed without requiring co-extrusion or barrier layers, and without any pigments, UV inhibitors, or processing agents that may adversely affect the purity requirements for components to be disposed in the liner. A listing of desirable liner materials include films comprising virgin (additive-free) polyethylene, virgin polytetrafluoroethylene (PTFE), polypropylene, polyurethane, polyvinylidene chloride, polyvinylchloride, polyacetal, polystyrene, polyacrylonitrile, polybutylene, and so on. Preferred thicknesses of such liner materials are in a range from about 5 mils (0.005 inch) to about 30 mils (0.030 inch), as for example a thickness of 20 mils (0.020 inch).

Regarding the containers for the kits, the disclosures of the following patents and patent applications are hereby incorporated herein by reference in their respective entireties: U.S. Pat. No. 7,188,644 entitled “APPARATUS AND METHOD FOR MINIMIZING THE GENERATION OF PARTICLES IN ULTRAPURE LIQUIDS;” U.S. Pat. No. 6,698,619 entitled “RETURNABLE AND REUSABLE, BAG-IN-DRUM FLUID STORAGE AND DISPENSING CONTAINER SYSTEM;” and U.S. Patent Application No. 60/916,966 entitled “SYSTEMS AND METHODS FOR MATERIAL BLENDING AND DISTRIBUTION” filed on May 9, 2007 in the name of John E. Q. Hughes, and PCT/US08/63276 entitled “SYSTEMS AND METHODS FOR MATERIAL BLENDING AND DISTRIBUTION” filed on May 9, 2008.

In removal application, the removal composition (e.g., the removal compositions of the fourth or fifth aspect) is applied in any suitable manner to the device substrate, e.g., by spraying the removal composition on the surface of the device substrate, by dipping the device substrate in a static or dynamic volume of the removal composition, by contacting the device substrate with another material, e.g., a pad, or fibrous sorbent applicator element, that has the removal composition absorbed thereon, or by any other suitable means, manner or technique by which the removal composition is brought into removal contact with the device substrate having the spin-on glass, the gate metal materials and/or the ILD materials. Further, batch or single wafer processing is contemplated herein.

Following the achievement of the desired removal action, the removal composition is readily removed from the device substrate to which it has previously been applied, e.g., by rinse, wash, or other removal step(s), as may be desired and efficacious. For example, the device substrate may be rinsed with a rinse solution including deionized water and/or dried (e.g., spin-dry, N₂, solvents (such as IPA) vapor-dry etc.).

Another aspect of the invention relates to the improved microelectronic devices made according to the methods of the invention and to products containing such microelectronic devices.

A still further aspect of the invention relates to methods of manufacturing an article comprising a microelectronic device, said method comprising contacting the microelectronic device with a removal composition for sufficient time to selectively remove spin-on glass relative to a metal gate and/or ILD material from the microelectronic device having said material thereon, and incorporating said microelectronic device into said article. The removal composition can comprise, consist of, or consist essentially of at least one fluoride, at least one metal corrosion inhibitor, water, and optionally at least one organic solvent. Alternatively, the removal compositions can comprise, consist essentially of, or consist of buffered fluoride, at least one metal corrosion inhibitor, water, and optionally at least one organic solvent. In still another alternative, the removal compositions can comprise, consist of, or consist essentially of at least one quaternary ammonium hydroxide or amine, at least one organic solvent, at least one alkali or alkaline earth metal salt, water, and optionally at least one metal corrosion inhibitor.

In still another aspect, a method of removing post-etch residue is described, said method comprising contacting a substrate comprising said post-etch residue with a removal composition of the fourth aspect, wherein the removal composition is useful for removing the post-etch residue from the substrate. For example, poly-silicon may be etched and the residue remaining can be removed using a composition of the fourth aspect. Preferably, the composition of the fourth aspect, first embodiment, having pH in a range from about 3 to about 7.

The features and advantages of the invention are more fully illustrated by the following non-limiting examples, wherein all parts and percentages are by weight, unless otherwise expressly stated.

### EXAMPLE 1

The following composition was prepared.
Composition A: 62.50 wt % ethylene glycol, 30.80 wt % DI water, 4.00 wt % NH₄F, 1.00 wt % HEDP (60 wt % aq. solution), 1.50 wt % IDA, 0.20 wt % NH₃ (conc.)

The pH of composition A was determined to be about 6.4. Blanketed wafers having a layer of titanium nitride, tantalum nitride, SOG and an ILD were individually immersed in composition A at 30° C. for 5, 5, 0.75 and 2 minutes, respectively. The etch rate of each nitride was determined to be less than 2 Å min⁻¹ The etch rate of SOG and ILD were 959 Å min⁻¹ and 123 Å min⁻¹, respectively, with a selectivity of SOG relative to ILD of 7.8:1. When the same composition was diluted with DI water at a weight ratio of 1:1, the respective etch rates of SOG and ILD under the same conditions as above decreased to 688 and 56 Å/min, respectively, for an improved selectivity of 12.4:1.

### EXAMPLE 2

The following composition was prepared.
Composition B: 71.43 wt % DI water, 17.86 wt % BTMAH (20 wt % aq. solution), 9.92 wt % DMSO, 0.79 wt % CsCl

The pH of composition B was determined to be about 14. Blanketed wafers having a layer of titanium nitride, tantalum nitride, SOG and an ILD were individually immersed in composition B at 60° C. for 1.5 minute. The etch rate of each nitride was determined to be less than 2 Å min⁻¹. The etch rate of SOG and ILD were ˜1800 Å min⁻¹ and ˜9 Å min⁻¹, respectively. Advantageously, the selectivity for SOG relative to ILD was about 200:1.

### EXAMPLE 3

The following composition was prepared.
Composition C: 3.50 wt % ammonium hexafluorosilicate, 1.72 wt % HFSA, 1 wt % NTMP, 93.78 wt % DI water.

The pH of composition C was determined to be less than 1. Blanketed wafers having a layer of titanium nitride, SOG and an ILD were individually immersed in composition C at 25° C. for 0.75, and 2 minutes, respectively. The etch rate of titanium nitride was determined to be 0.7 Å min⁻¹ The etch rates of SOG and ILD were 650 Å min⁻¹ and 37.4 Å min⁻¹, respectively, with the selectivity for SOG relative to ILD of 17.4:1.

A closely related set of data shows that reasonable TiN etch rate with slightly better SOG/ILD selectivity can be obtained with much lower inhibitor concentration. Specifically, the composition comprises 3.50% AHFS, 1.72% HFSA, 0.25% NTMP and 94.03% DI water. The SOG etch rates were 689 Å/min and the ILD etch rates were 36.8 Å/min, the selectivity for SOG relative to ILD of 18.7:1, and the etch rate of TiN was 2.2 Å/min.

### EXAMPLE 4

Composition D was prepared having the following components:
Composition D

| | |
|---|---|
| deionized water: | 28.28 wt % |
| ammonium fluoride (96%) | 3.67 wt % |
| IDA | 1.43 wt % |
| HEDP (60%) | 1.59 wt % |
| propylene glycol | 59.65 wt % |
| catechol | 0.48 wt % |
| alkyl phosphate (KC-212) | 0.24 wt % |
| TMAH (25%) | 4.66 wt % |

pH = about 5.2 to about 5.5

Coupons of spin-on glass (SOG), TiN, TaN and Al/AlOₓ were immersed in the formulation at 25° C. and the etch rate of same determined. The etch rate of SOG was 880-900 Å/min, for TiN was <0.3 Å/min, no noticeable damage to TaN. With regards to the Al/AlOₓ coupon, AlOₓ was removed without any damage to the Al. Accordingly, a removal composition that selectively removes SOG relative to metal gate material and that does not corrode aluminum has been formulated.

Additional removal compositions that selectively remove SOG relative to metal gate material and that do not corrode aluminum have the general formulation: about 25 wt % to about 35 wt % DIW, about 3 wt % to about 5 wt % ammonium fluoride, about 1 wt % to about 2 wt % IDA, about 0.5 wt % to about 1.5 wt % HEDP, about 57 wt % to about 70 wt % glycol solvent (e.g., EG or PG), about 0.5 wt % to about 2 wt % quaternary base (e.g., NH₄OH or TMAH), about 0.1 wt % to about 0.5 wt % alkyl phosphate, and optionally about 0.1 wt % to about 1 wt % catechol. The pH is in a range from about 5.2 to about 5.5.

### EXAMPLE 5

Post-etch residue removal compositions were prepared that had the general formula: about 15 wt % to about 35 wt % DIW, about 0.5 wt % to about 1.5 wt % ammonium fluoride, about 0.25 wt % to about 2 wt % IDA, about 0.1 wt % to about 1 wt % HEDP, about 55 wt % to about 80 wt % glycol and/or glycol ether solvent (e.g., EG, PG, glycol ethers), about 0.1 wt % to about 1 wt % quaternary base (e.g., NH₄OH or TMAH), and about 0.1 wt % to about 0.5 wt % alkyl phosphate. The pH is in a range from about 5.2 to about 5.5. These compositions will be used to remove post poly-Si etch residue.

Although the invention has been variously disclosed herein with reference to illustrative embodiments and features, it will be appreciated that the embodiments and features described hereinabove are not intended to limit the invention, and that other variations, modifications and other embodiments will suggest themselves to those of ordinary skill in the art, based on the disclosure herein. The invention therefore is to be broadly construed, as encompassing all such variations, modifications and alternative embodiments within the spirit and scope of the claims hereafter set forth.

1. A method of selectively removing spin-on glass relative to a material selected from the group consisting of metal gate material, ILD material, and combinations thereof, said method comprising contacting a substrate comprising the spin-on glass and the material with a removal composition, wherein the removal composition selectively removes the spin-on glass relative to the material.

2. The method of claim 1, wherein the metal gate material comprises titanium.

3. The method of claim 1, wherein the ILD material comprises low-k dielectric material.

4. The method of claim 1, wherein the removal rate of the metal gate material is less than about 2 Å min⁻¹.

5. The method of claim 1, wherein the removal rate of the ILD is less than about 50 Å min⁻¹.

6. The method of claim 1, wherein the removal rate of SOG is in a range from about 500 to about 2000 Å min⁻¹.

7. The method of claim 1, wherein the removal composition comprises at least one fluoride, at least one metal corrosion inhibitor, water, and at least one organic solvent.

8. The method of claim 7, wherein the pH of the removal composition is less than about 7.

9. The method of claim 7, wherein the at least one fluoride source comprises a species selected from the group consisting of hydrofluoric acid, ammonium fluoride, ammonium bifluoride, hexafluorosilicic acid (HFSA), ammonium hexafluorosilicate, tetrafluoroboric acid, ammonium tetrafluoroborate, tetrabutylammonium tetrafluoroborate (TBA-BF₄), hexafluorotantalic acid, ammonium hexafluorotantalate, and combinations thereof.

10. The method of claim 7, wherein the at least one fluoride source comprises ammonium fluoride.

11. The method of claim 7, wherein the at least one metal corrosion inhibitor comprises a species selected from the group consisting of boric acid, ammonium borates, ascorbic acid, L(+)-ascorbic acid, isoascorbic acid, ascorbic acid derivatives, gallic acid, glycine, serine, proline, leucine, alanine, asparagine, aspartic acid, glutamine, valine, lysine, iminodiacetic acid (IDA), boric acid, nitrilotriacetic acid, malic acid, acetic acid, maleic acid, 2,4-pentanedione, 1-hydroxyethylidene-1,1-diphosphonic acid (HEDP), 1-hydroxyethane-1,1-diphosphonic acid, nitrilotris(methylenephosphonic acid) (NTMP), N,N,N′,N′-ethylenediaminetetra(methylenephosphonic)acid (EDTMP), 1,5,9-triazacyclododecane-N,N′,N″-tris(methylenephosphonic acid) (DOTRP), 1,4,7,10-tetraazacyclododecane-N,N′,N″,N′″-tetrakis(methylenephosphonic acid) (DOTP), diethylenetriaminepenta(methylenephosphonic acid) (DETAP), aminotri(methylenephosphonic acid), bis(hexamethylene)triamine phosphonic acid, 1,4,7-triazacyclononane-N,N′,N″-tris(methylenephosphonic acid (NOTP), esters of phosphoric acids; 5-amino-1,3,4-thiadiazole-2-thiol (ATDT), benzotriazole (BTA), citric acid, ethylenediamine, oxalic acid, tannic acid, ethylenediaminetetraacetic acid (EDTA), uric acid, 1,2,4-triazole (TAZ), tolyltriazole, 5-phenyl-benzotriazole, 5-nitro-benzotriazole, 3-amino-5-mercapto-1,2,4-triazole, 1-amino-1,2,4-triazole, hydroxybenzotriazole, 2-(5-amino-pentyl)-benzotriazole, 1-amino-1,2,3-triazole, 1-amino-5-methyl-1,2,3-triazole, 3-amino-1,2,4-triazole, 3-mercapto-1,2,4-triazole, 3-isopropyl-1,2,4-triazole, 5-phenylthiol-benzotriazole, halo-benzotriazoles, naphthotriazole, 2-mercaptobenzimidazole (MBI), 2-mercaptobenzothiazole, 4-methyl-2-phenylimidazole, 2-mercaptothiazoline, 5-aminotetrazole, 2,4-diamino-6-methyl-1,3,5-triazine, thiazole, triazine, methyltetrazole, 1,3-dimethyl-2-imidazolidinone, 1,5-pentamethylenetetrazole, 1-phenyl-5-mercaptotetrazole, diaminomethyltriazine, imidazoline thione, mercaptobenzimidazole, 4-methyl-4H-1,2,4-triazole-3-thiol, benzothiazole, tritolyl phosphate, imidazole, indiazole, benzoic acid, malonic acid, ammonium benzoate, catechol, 4-tert butyl catechol, pyrogallol, resorcinol, hydroquinone, cyanuric acid, barbituric acid and derivatives such as 1,2-dimethylbarbituric acid, alpha-keto acids such as pyruvic acid, adenine, purine, glycine/ascorbic acid, Dequest 2000, Dequest 7000, p-tolylthiourea, succinic acid, phosphonobutane tricarboxylic acid (PBTCA), alkyl phosphates, phosphoric acid, and combinations thereof.

12. The method of claim 7, wherein the at least one metal corrosion inhibitor comprises HEDP, NTMP, IDA, or any combination thereof.

13. The method of claim 7, wherein the removal composition further comprises at least one buffering agent selected from the group consisting of a salt of the conjugate base of the fluoride source, ammonia, and quaternary ammonium bases.

14. The method of claim 7, wherein the at least one organic solvent comprises a glycol solvent selected from the group consisting of ethylene glycol, propylene glycol, diethylene glycol, dipropylene glycol, glycerol, a monoglyceride, a diglyceride, a glycol ether, and combinations thereof.

15. The method of claim 7, wherein the glycol solvent comprises ethylene glycol.

16. The method of claim 7, wherein the removal composition comprises a buffered fluoride, a glycol solvent, a phosphonic acid, and water.

17. The method of claim 7, wherein the removal composition comprises NH₄F, HEDP, IDA, ethylene glycol, and water.

18. The method of claim 7, wherein the pH of the removal composition is in a range from about 3 to about 7.

19. The method of claim 7, wherein the removal composition is substantially devoid of abrasive or other inorganic particulate material, silicic acid, surfactant(s), oxidizing agent(s), polymeric species, or any combination thereof.

20. The method of claim 7, wherein the removal composition further comprises dissolved spin-on glass.
